(19) United States
(12) Patent Application Publication
(10) Pub. No.: US 2024/0027890 A1
(43) Pub. Date: Jan. 25, 2024

(54) REFLECTIVE MASK AND METHOD OF DESIGNING ANTI-REFLECTION PATTERN OF THE SAME

(71) Applicant: Samsung Electronics Co., Ltd., Suwon-si (KR)

(72) Inventors: Hyungjong Bae, Suwon-si (KR); Hyun Jung Hwang, Suwon-si (KR); Heebom Kim, Suwon-si (KR); Seong-Bo Shim, Suwon-si (KR); Seungyoon Lee, Suwon-si (KR); Woo-Yong Jung, Suwon-si (KR); Chan Hwang, Suwon-si (KR)

(21) Appl. No.: 18/180,210

(22) Filed: Mar. 8, 2023

(30) Foreign Application Priority Data
Jul. 25, 2022 (KR) 10-2022-0091843

(51) Int. Cl. G03F 1/24; G03F 1/42; G03F 1/54; G03F 1/80

(52) U.S. Cl. CPC G03F 1/24; G03F 1/42; G03F 1/54; G03F 1/80

(57) ABSTRACT

A reflective mask used in an EUV exposure process includes a mask substrate, a reflective layer on the mask substrate, and an absorption layer on the reflective layer. The reflective mask includes a main region, an out-of-band region surrounding the main region, and an alignment mark region outside a periphery of the out-of-band region. The absorption layer in the alignment mark region includes an alignment mark and an anti-reflection pattern adjacent the alignment mark, and the anti-reflection pattern includes line-and-space patterns having a predetermined line width in the alignment mark region.

### CROSS-REFERENCE TO RELATED APPLICATIONS

This U.S. non-provisional patent application claims priority under 35 U.S.C.§ 119 to Korean Patent Application No.10-2022-0091843, filed on Jul. 25, 2022, in the Korean Intellectual Property Office, the entire contents of which are hereby incorporated by reference.

### FIELD

The inventive concept relates to a reflective mask used in an EUV exposure process and a method for designing an anti-reflection pattern used therein.

### BACKGROUND

As an integration density of a semiconductor device increases, demand for high resolution lithography systems is increasing. Thus, an extreme ultraviolet (EUV) exposure system, in which an EUV light having a shorter wavelength than a deep ultraviolet (DUV) light, is used as a source light, is being developed. A reflective mask reflecting the EUV light is used for the EUV exposure system.

### SUMMARY

Embodiments of the inventive concept provide a reflective mask capable of achieving an EUV lithography process with improved precision and resolution.

Embodiments of the inventive concept provide a method of designing an anti-reflection pattern of a reflective mask.

A reflective mask according to some embodiments of the inventive concept may include a mask substrate, a reflective layer on the mask substrate, and an absorption layer on the reflective layer. The reflective mask comprises a main region, an out-of-band region surrounding the main region, and an alignment mark region outside a periphery of the out-of-band region. The absorption layer in the alignment mark region comprises an alignment mark and an anti-reflection pattern adjacent the alignment mark, and the anti-reflection pattern comprises line-and-space patterns having a predetermined line width and a predetermined pitch in the alignment mark region.

An extreme ultraviolet (EUV) phase shift mask according to some embodiments of the inventive concept may include a mask substrate, a reflective layer on the mask substrate, and an absorption layer on the reflective layer. The EUV phase shift mask comprises a main region, an out-of-band region surrounding the main region, and an alignment mark region outside a periphery of the out-of-band region. The absorption layer in the alignment mark region comprises an alignment mark and an anti-reflection pattern adjacent the alignment mark. The alignment mark is configured to provide a first reflectance in the alignment mark region, and the anti-reflection pattern is configured to provide a second reflectance that is less than the first reflectance in the alignment mark region.

A reflective mask according to some embodiments of the inventive concept may include a mask substrate, a reflective layer on the mask substrate, and an absorption layer on the reflective layer. The reflective mask may include a main region, an out-of-band region surrounding the main region, and an alignment mark region outside a periphery of the out-of-band region, and the absorption layer in the alignment mark region may include an alignment mark and an anti-reflection pattern adjacent the alignment mark. A method of designing a reflective mask according to some embodiments of the inventive concept may include executing, by a processor, computer readable program instructions stored in a non-transitory storage medium to perform operations comprising: performing optical simulation during which a line width and a pitch of line-and-space patterns in the absorption layer in the alignment mark region, and an interval between the line-and-space patterns and the alignment mark, are changed; calculating a parabolic width from an aerial image intensity resulting from the optical simulation; and determining the line width, the pitch, and the interval based on a result of the calculating in which the parabolic width is smaller than a threshold.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram illustrating an EUV exposure apparatus according to embodiments of the inventive concept.

FIG. 2 is a plan view schematically illustrating a reflective mask applied to an EUV exposure apparatus of FIG. 1.

FIG. 3 is a plan view illustrating a peripheral region of a reflective mask of FIG. 2, specifically.

FIG. 4 is a cross-sectional view taken along line I-I′ of FIG. 3.

FIG. 5 is a schematic diagram for illustrating an alignment process with a wafer using a reflective mask according to a comparative example of the inventive concept.

FIG. 6 illustrates an aerial image intensity when an alignment sensor shown in FIG. 5 scans an alignment mark region.

FIG. 7 is a schematic diagram for explaining an alignment process with a wafer using a reflective mask according to an embodiment of the inventive concept.

FIG. 8 illustrates an aerial image intensity when an alignment sensor shown in FIG. 7 scans an alignment mark region.

FIG. 9 is a plan view illustrating a fifth alignment mark of a first alignment mark region of a reflective mask of FIG. 3 according to an embodiment of the inventive concept, specifically.

FIG. 10 is a cross-sectional view taken along line II-II′ of FIG. 9.

FIG. 11 is a plan view illustrating a fifth alignment mark in a first alignment mark region of a reflective mask of FIG. 3 according to another embodiment of the inventive concept.

FIG. 12 is a cross-sectional view taken along line II-II′ of FIG. 11.

FIG. 13 is a plan view illustrating a fifth alignment mark of a first alignment mark region of a reflective mask of FIG. 3 according to another embodiment of the inventive concept, specifically.

FIG. 14 is a flowchart illustrating a method of designing an anti-reflection pattern according to embodiments of the inventive concept.

FIGS. 15, 16, 17, and 18 are diagrams for illustrating a method of manufacturing a semiconductor device according to embodiments of the inventive concept.

### DETAILED DESCRIPTION

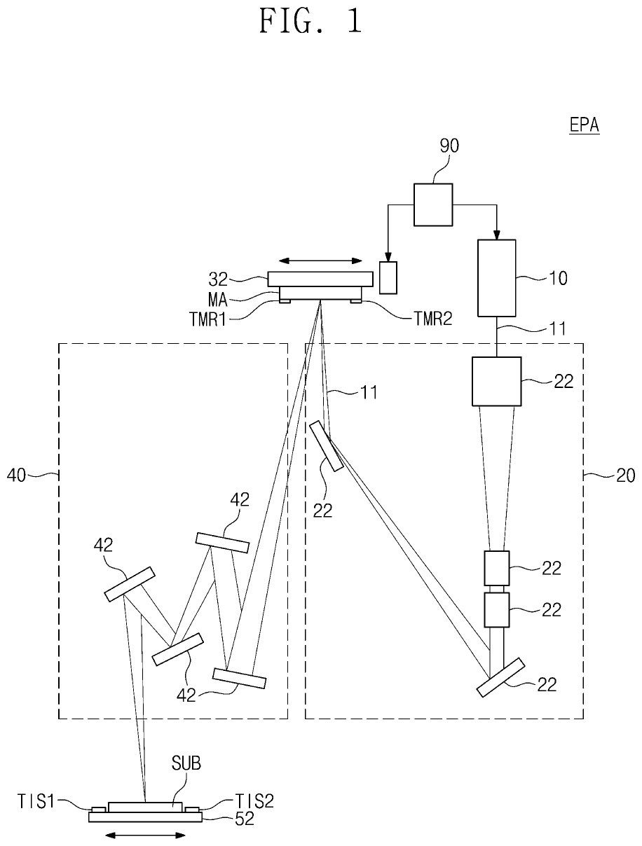

FIG. 1 is a schematic diagram illustrating an EUV exposure apparatus according to embodiments of the inventive concept. Referring to FIG. 1, an EUV exposure apparatus EPA may include an optical light source unit 10, a condenser unit 20, a projection unit 40, and a controller 90. The light source unit 10 may generate extreme ultraviolet (EUV) light, for example, light having a wavelength of 4 nm to 124 nm. In an embodiment, the light source unit may generate EUV light, for example, light having a wavelength of 13.5 nm. The light source unit 10 may generate light having an energy of 6.21 eV to 124 eV, specifically, 90 eV to eV.

The light source unit 10 generates the EUV light, but may undesirably generate DUV light, for example, light having a wavelength of 100 nm or more and 300 nm or less. The condenser unit 20 serves to guide a light 11 such that the light 11 generated by the light source unit 10 is reflected by a reflective mask MA mounted on a mask stage 32.

The condenser unit 20 includes a condenser optics 22, for example, a lens or a mirror. The condenser optics 22 collects and reflects the light 11 and guides the light 11 to the reflective mask MA. The light 11 may be inclinedly incident on the reflective mask MA through the condenser unit 20. The mask stage 32 may move the reflective mask MA depending on a scan direction of the reflective mask MA. The light source unit 10 and the mask stage 32 may be controlled by the controller 90.

The light 11 incident on the reflective mask MA may be reflected by the reflective mask MA and may be inclinedly incident (i.e., incident at non-orthogonal angle) on the projection unit The projection unit 40 serves to project the mask pattern (absorption pattern) of the reflective mask MA onto a substrate SUB positioned on a substrate stage 52. For example, the substrate SUB may be a silicon wafer on which an integrated circuit is formed. A photoresist capable of reacting to light is coated on the substrate SUB. The substrate stage 52 may move the substrate SUB to change an exposure region (or exposure position) of the substrate SUB.

The projection unit 40 includes a reflective projection optics 42, for example, a lens. The reflective projection optics 42 may reduce a mask pattern on the reflective mask MA by a predetermined magnification, for example, 4 times, 6 times, or 8 times to be projected onto the substrate SUB, using the light 11 obliquely reflected from the reflective mask MA.

According to embodiments of the inventive concept, the substrate stage 52 may include a first alignment sensor TIS1 and a second alignment sensor TIS2. The first and second alignment sensors TIS1 and TIS2 may be disposed adjacent to both (e.g., opposing) sides of the substrate SUB, respectively. The reflective mask MA may include a first alignment mark region TMR1 and a second alignment mark region TMR2 respectively disposed on both (e.g., opposing) sides thereof. The terms first, second, etc. may be used herein merely to distinguish one element or region from another.

To perform an exposure process from the reflective mask MA to the substrate SUB using the EUV exposure apparatus EPA, the reflective mask MA and the substrate SUB should be accurately aligned. The first and second alignment mark regions TMR1 and TMR2 may include alignment marks for the alignment. The first and second alignment sensors TIS1 and TIS2 may read the first and second alignment mark regions TMR1 and TMR2, respectively.

Reading the first alignment mark region TMR1 by the first alignment sensor TIS1 may include generating light from the light source unit 10 to irradiate the light to the first alignment mark region TMR1 through the condenser unit 20 and irradiating (or projecting) the light reflected from the first alignment mark region TMR1 to the first alignment sensor TIS1 through the projection unit 40. Reading the second alignment mark region TMR2 by the second alignment sensor TIS2 may include generating light from the light source unit 10 to irradiate the light to the second alignment mark region TMR2 through the condenser unit 20 and irradiating (or projecting) the light reflected from the second alignment mark region TMR2 to the second alignment sensor TIS2 through the projection unit 40.

The reading of the first alignment mark region TMR1 by the first alignment sensor TIS1 and the reading of the second alignment mark region TMR2 by the second alignment sensor TIS2 may be performed simultaneously or sequentially. In an embodiment of the inventive concept, each of the first and second alignment sensors TIS1 and TIS2 may include a transmission image sensor (TIS). The first and second alignment sensors TIS1 and TIS2 may sense or detect EUV light.

Before the exposure process, the first and second alignment sensors TIS1 and TIS2 may read the first and second alignment mark regions TMR1 and TMR2, respectively, and thus may be determined whether the reflective mask MA and the substrate SUB are correctly aligned. When there is misalignment between the reflective mask MA and the substrate SUB, the controller 90 may move the mask stage 32 and/or the substrate stage 52 to align the reflective mask MA and the substrate SUB. When the reflective mask MA and the substrate SUB are aligned with each other as a result of reading the first and second alignment sensors TIS1 and TIS2, an exposure process may be performed.

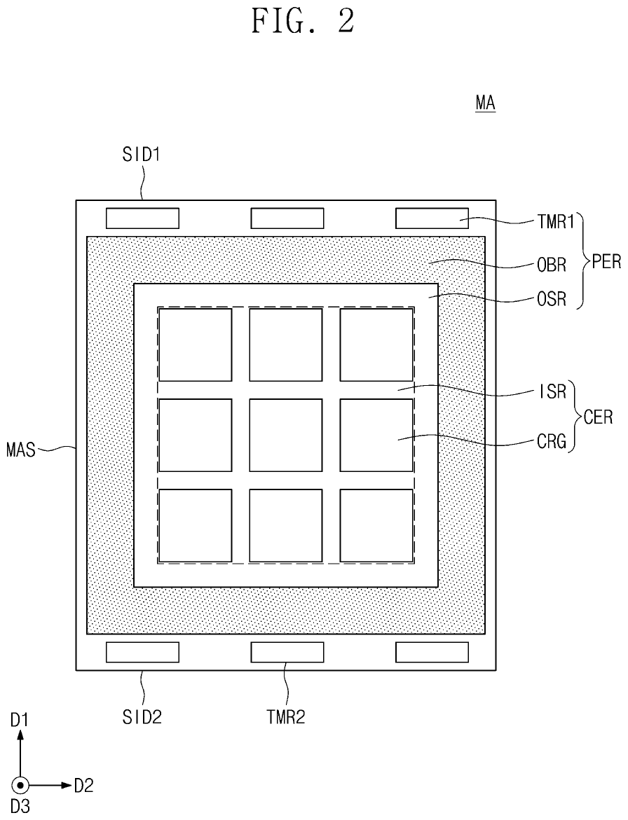

FIG. 2 is a plan view schematically illustrating a reflective mask applied to or used in the EUV exposure apparatus of FIG. 1. Referring to FIG. 2, a reflective mask MA may include a central region CER and a peripheral region PER surrounding the central region CER. As used herein, an element or region that is “surrounding” another element or region may partially or completely surround the element or region.

The central region CER may include main regions CRG and an inner auxiliary region ISR between the main regions CRG. The main regions CRG may respectively correspond to chip regions (or dies) of the substrate SUB of FIG. 1. Each of the main regions CRG may transfer patterns constituting an integrated circuit in the chip region of the substrate SUB of FIG. 1. The main regions CRG may be two-dimensionally arranged. The inner auxiliary region ISR may transfer auxiliary patterns in a scribe line region on the substrate SUB of FIG. 1.

The peripheral region PER may include an outer auxiliary region OSR, an out-of-band region OBR, and first and second alignment mark regions TMR1 and TMR2. The outer auxiliary region OSR may surround the central region CER. The outer auxiliary region OSR may transfer the auxiliary patterns in the scribe line region on the substrate SUB of FIG. 1, similarly to the inner auxiliary region ISR.

The out-of-band region OBR may constitute an edge of the reflective mask MA. The out-of-band region OBR may absorb or scatter light incident on the reflective mask MA without reflecting the light. For example, the out-of-band region OBR may absorb EUV light and may scatter DUV light.

The central region CER and the outer auxiliary region OSR of the reflective mask MA may reflect light incident on the reflective mask MA. That is, patterns formed in the central region CER and the outer auxiliary region OSR, which are inside the perimeter or periphery of the out-of-band region OBR, may be transferred onto the substrate SUB of FIG. 1. Because the light is not reflected in the out-of-band region OBR, patterns formed on the out-of-band region OBR may not be transferred onto the substrate SUB.

The mask substrate MAS may include a first side SID1 and a second side SID2 opposite to each other in a first direction D1. The first alignment mark region TMR1 may be provided between the first side SID1 and the out-of-band region OBR. The second alignment mark region TMR2 may be provided between the second side SID2 and the out-of-band region OBR.

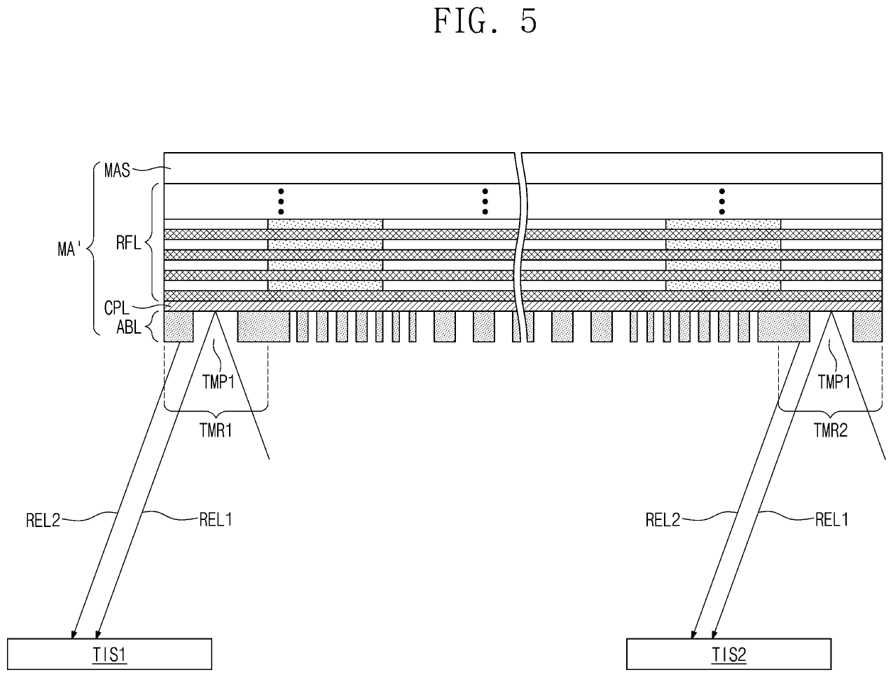

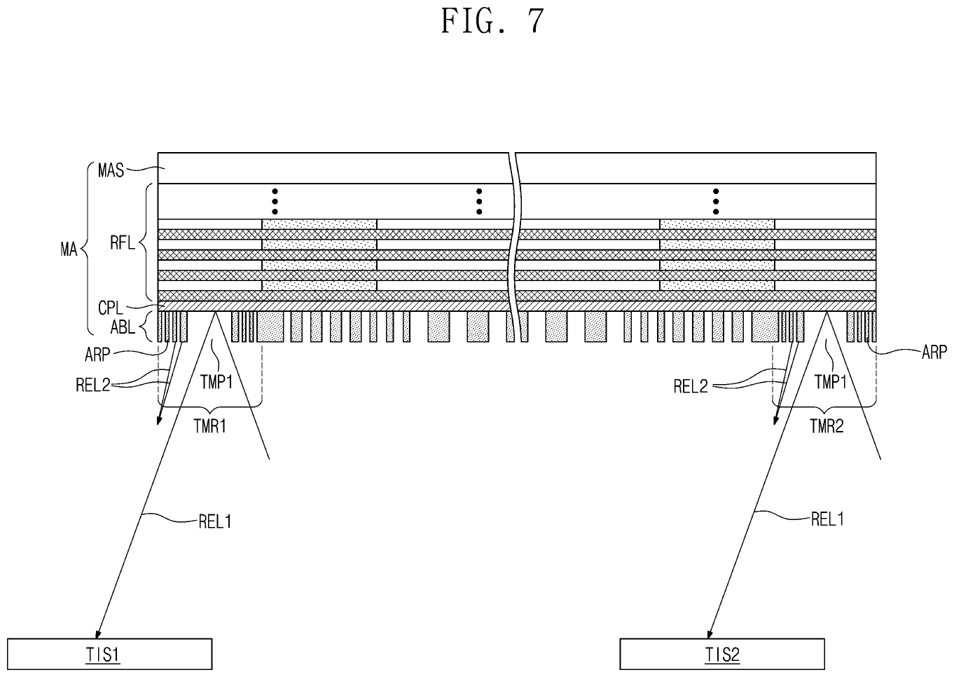

The first and second alignment mark regions TMR1 and TMR2 may be provided outside the out-of-band region OBR (i.e., outside a perimeter or periphery of the out-of-band region OBR), and thus optical density (OD) process, which will be described later, may not be performed. Accordingly, the first and second alignment mark regions TMR1 and TMR2 may reflect the light incident on the reflective mask MA. However, the light reflected from the first and second alignment mark regions TMR1 and TMR2 may not be projected onto the substrate SUB, but may be irradiated to the first and second alignment sensors TIS1 and TIS2 of the substrate stage 52 (refer to FIGS. 5 and 7 to be described later).

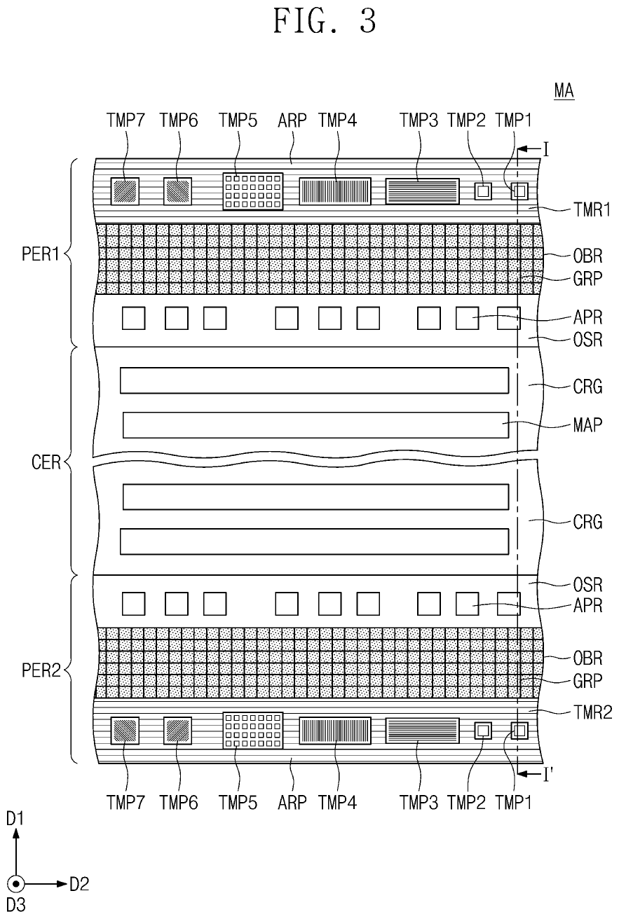

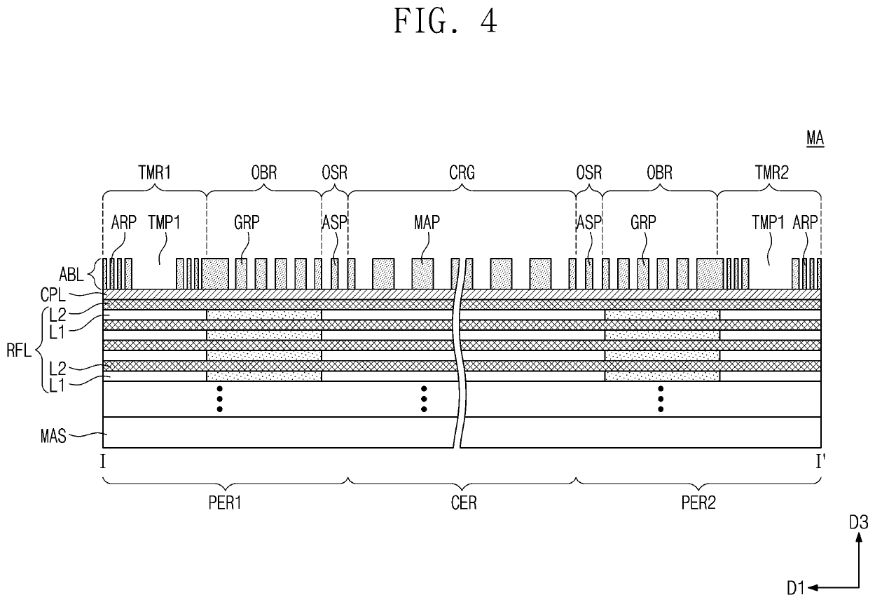

FIG. 3 is a plan view illustrating a peripheral region of a reflective mask of FIG. 2, specifically. FIG. 4 is a cross-sectional view taken along line I-I′ of FIG. 3.

Referring to FIG. 3, a reflective mask MA may include a central region CER and first and second peripheral regions PER1 and PER2 respectively disposed on both (e.g., opposing) sides thereof. The first peripheral region PER1 may include a first alignment mark region TMR1, and the second peripheral region PER2 may include a second alignment mark region TMR2.

The first alignment mark region TMR1 may include a plurality of alignment marks TMP1 to TMP7 arranged in a second direction D2. For example, the plurality of alignment marks TMP1 to TMP7 may include first to seventh alignment marks TMP1 to TMP7. Each of the first to seventh alignment marks TMP1 to TMP7 may include a plurality of mark patterns constituting the first to seventh alignment marks TMP1 to TMP7. The first to seventh alignment marks TMP1 to TMP7 may include different types of mark patterns.

For example, the first alignment mark TMP1 may include one mark pattern having a tetragonal shape. The second alignment mark TMP1 may include a mark pattern that is the same as or different from the first alignment mark TMP1. The third alignment mark TMP3 may include line-shaped mark patterns extending parallel to each other in the second direction D2. The fourth alignment mark TMP4 may include line-shaped mark patterns extending parallel to each other in a first direction Dl. The fifth alignment mark TMP5 may include mark patterns in a form of two-dimensionally arranged contacts. The sixth alignment mark TMP6 may include line-shaped mark patterns extending at an angle of 135° from the second direction D2. The seventh alignment mark TMP7 may include line-shaped mark patterns extending at an angle of 45° from the second direction D2.

The first alignment mark region TMR1 may further include an anti-reflection pattern ARP surrounding the first to seventh alignment marks TMP1 to TMP7. In an embodiment of the inventive concept, the anti-reflection pattern ARP may include line-and-space patterns extending parallel to each other in the second direction D2. In another embodiment of the inventive concept, the anti-reflection pattern ARP may include patterns in a form of two-dimensionally arranged contacts. The patterns constituting the anti-reflection pattern ARP may have the same shape (or size) as each other and may be repeatedly arranged at a constant pitch.

The second alignment mark region TMR2 may be positioned opposite to the first alignment mark region TMR1 on the reflective mask MA. A description of the second alignment mark region TMR2 may be substantially the same as that of the first alignment mark region TMR1.

Each of the first and second peripheral regions PER1 and PER2 may include an outer auxiliary region OSR and an out-of-band region OBR between the outer auxiliary region OSR and the alignment mark regions TMR1 and TMR2. The outer auxiliary region OSR may include auxiliary pattern regions APR. Each of the auxiliary pattern regions APR may include patterns defining auxiliary patterns (e.g., key patterns) in a scribe line region. The central region CER may include a plurality of main patterns MAP defining circuit patterns in a chip region.

Referring to FIGS. 3 and 4, the reflective mask MA according to embodiments of the inventive concept may include a mask substrate MAS (a reticle substrate), a reflective layer RFL, a capping layer CPL, and an absorption layer ABL.

The mask substrate MAS may be a glass or quartz substrate. The reflective layer RFL may be disposed on the mask substrate MAS. The reflective layer RFL may reflect incident light. The reflective layer RFL may have, for example, a multilayer structure in which first layer L1/second layer L2 are repeatedly stacked 30 to 60 times. For example, the first layer L1 may include silicon (Si) and/or a silicon compound. The second layer L2 may include molybdenum (Mo) and/or a molybdenum compound.

The capping layer CPL may be provided on the reflective layer RFL to protect the reflective layer RFL. For example, the capping layer CPL may include ruthenium (Ru) or ruthenium oxide. In another embodiment of the inventive concept, although not shown, the capping layer CPL may be omitted.

The absorption layer ABL may be provided on the capping layer CPL. The absorption layer ABL may include an inorganic material or a metal. The absorption layer ABL may include a ruthenium alloy, a tantalum alloy, a tantalum-based compound (TaN, TaBN, or TaBON), or a combination thereof. For example, the ruthenium alloy may include ruthenium (Ru), chromium (Cr), nickel (Ni), and/or cobalt (Co). The tantalum alloy may include tantalum (Ta), chromium (Cr), nickel (Ni), and/or cobalt (Co). In addition, the absorption layer ABL of the inventive concept may be used without limitation as long as a material is an in organic material or metal (e.g., Cr, CrO, Ni, Cu, Mo, Al, Ti, W or Ru) that is opaque to light. The absorption layer ABL may be exposed to the outside of the reflective mask MA.

The reflective mask MA according to embodiments of the inventive concept may be an EUV phase shift mask (PSM). For example, EUV PSM may use the absorption layer ABL based on a ruthenium alloy. EUV PSM may have a higher resolution in EUV lithography process than a resolution of EUV binary mask.

Meanwhile, the absorption layer ABL of the EUV PSM may have a higher EUV reflectance than a EUV reflectance of an absorption layer ABL of the EUV binary mask. For example, the absorption layer ABL of the EUV binary mask may have an EUV reflectance of about 3%, but the absorption layer ABL of the EUV PSM may have an EUV reflectance of 10% or more. The high reflectance of the absorption layer ABL of the EUV PSM may improve resolution of patterning and performance of the patterning process in the EUV lithography process.

However, the high reflectance of the absorption layer ABL of the EUV PSM may adversely affect the reading of the alignment mark regions TMR1 and TMR2 with the alignment sensors TIS1 and TIS2 described above in FIG. 1. In detail, when the EUV light reflected from the alignment mark regions TMR1 and TMR2 is input to the alignment sensors TIS1 and TIS2, a problem of increasing aerial image intensity may occur. When the aerial image intensity is high, align signal contrast may be low, and alignment failure through the alignment sensors TIS1 and TIS2 may occur.

According to embodiments of the inventive concept, the anti-reflection pattern ARP in each of the first and second alignment mark regions TMR1 and TMR2 may be provided, and thus the EUV reflectance of the absorption ABL of the first and second alignment mark regions TMR1 and TMR2 may be lowered. Therefore, the alignment sensors TIS1 and TIS2 accurately read the alignment mark regions TMR1 and TMR2, and thus a problem of misalignment or inability to read alignment which is possible in EUV PSM may be addressed.

The absorption layer ABL of the out-of-band region OBR may include grating patterns GRP. That is, the absorption layer ABL of the out-of-band region OBR may have a lattice shape. The grating patterns GRP of the absorption layer ABL may scatter incident light. For example, the grating patterns GRP may effectively scatter the DUV light to prevent the DUV light from being reflected.

The reflective layer RFL of the out-of-band region OBR may be configured to prevent the reflective layer RFL from reflecting light, for example, through an optical density (OD) process such as laser annealing. In other words, portions of the reflective layer RFL in the out-of-band region OBR may absorb light. For example, a portion of the first layer L1 in the out-of-band region OBR may be changed from silicon (Si) to silicon nitride (SiN) through the optical density process.

Meanwhile, the optical density (OD) process may be excluded in the alignment mark regions TMR1 and TMR2 and the outer auxiliary region OSR except for the out-of-band region OBR. In other words, portions of the reflective layer RFL in the alignment mark regions TMR1 and TMR2 and the outer auxiliary region OSR may be unaltered or may maintain reflective properties so as to smoothly reflect light (e.g., EUV).

The absorption layer ABL of the outer auxiliary region OSR may include a plurality of auxiliary patterns ASP. The auxiliary patterns ASP may have a constant or uniform width and/or a constant or uniform pitch. The absorption layer ABL of the main region CRG may include a plurality of main patterns MAP.

Referring back to FIG. 4, the absorption layer ABL of each of the first and second alignment mark regions TMR1 and TMR2 may include an anti-reflection pattern ARP and a first alignment mark TMP1. In detail, each of the anti-reflection pattern ARP and the first alignment mark TMP1 may have a hole or trench shape in which the absorption layer ABL is patterned. Each of the anti-reflection pattern ARP and the first alignment mark TMP1 may expose the reflective layer RFL. In an embodiment, the anti-reflection pattern ARP may include a plurality of trenches formed in the absorption layer ABL. The first alignment mark TMP1 may include one hole or opening formed in the absorption layer ABL, which may be wider than the trenches in the absorption layer ABL that define the anti-reflection pattern ARP. That is, the trenches in the absorption layer ABL that define the anti-reflection pattern ARP may be narrower or otherwise smaller (e.g., in the first direction D1) than the holes or openings in the anti-reflection pattern ARP that define the alignment marks TMP1 to TMP7. In some embodiments, the trenches in the absorption layer ABL that define the anti-reflection pattern ARP in the alignment mark regions TMR1, TMR2 may have a finer or different pitch (e.g., in the first direction D1) than the grating patterns GRP in the out-of-band region OBR.

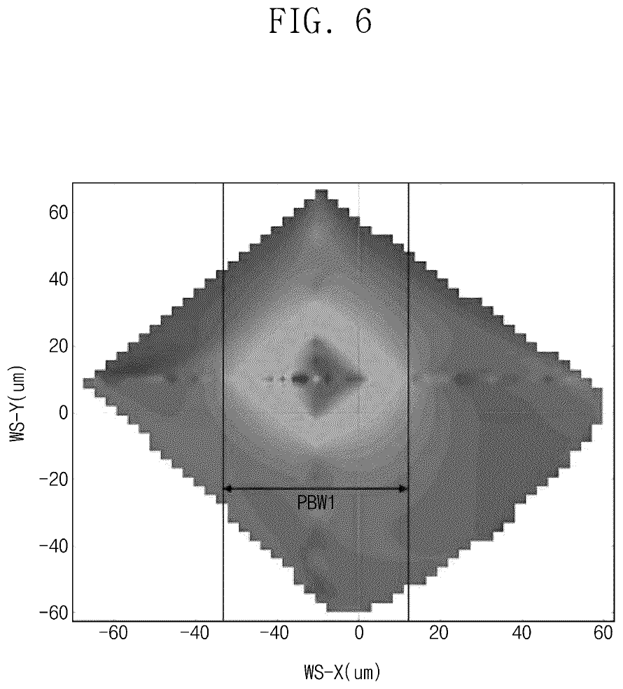

FIG. 5 is a schematic diagram for illustrating an alignment process with a wafer using a reflective mask according to a comparative example of the inventive concept. FIG. 6 illustrates an aerial image intensity when an alignment sensor shown in FIG. 5 scans an alignment mark region.

Referring to FIG. 5, a reflective mask MA′ according to the comparative example of the inventive concept, an anti-reflection pattern ARP may be omitted in each of first and second alignment mark regions TMR1 and TMR2. As the anti-reflection pattern ARP is omitted, the remaining regions of the alignment mark regions TMR1 and TMR2 excluding the alignment mark TMP1 may be formed of only the absorption layer ABL. That is, the absorption layer ABL may be unpatterned or may continuously extend in portions of the alignment mark regions TMR1 and TMR2 outside of the alignment marks.

Light for scanning of a first alignment sensor TIS1 may be reflected from the first alignment mark region TMR1. The light reflected from the first alignment mark region TMR1 may include a first reflected light REL1 and a second reflected light REL2. The first reflected light REL1 may be reflected from the first alignment mark TMP1. The second reflected light REL2 may be reflected from the absorption layer ABL around the first alignment mark TMP1. As described above, in the EUV PSM, because the absorption layer ABL has a relatively high EUV reflectance, the second reflected light REL2 may have a relatively high intensity. For example, the intensity of the second reflected light REL2 may be greater than 10% of the intensity of the first reflected light REL1.

Ideally, only the first reflected light REL1 may be incident to the first alignment sensor TIS1, but the second reflected light REL2 may also be incident. This may cause signal noise, increase aerial image intensity, and lower align signal contrast. As a result, the first alignment sensor TIS1 may erroneously scan the first alignment mark region TMR1, and thus an alignment failure may occur.

Light for scanning of the second alignment sensor TIS2 may be reflected from the second alignment mark region TMR2. Descriptions thereof may be substantially the same as those described above for the first alignment sensor TIS1 and the first alignment mark region TMR1. Referring to FIG. 6, a scan signal of the first alignment mark TMP1 of the reflective mask MA′ according to a comparative example of the inventive concept is illustrated. The scan signal of FIG. 6 may represent aerial image intensity.

In the aerial image intensity, a width of intensity points having half the maximum intensity may be defined as a parabola or parabolic width. The parabolic width of FIG. 6 may have a first width PBW1. For example, the first width PBW1 may be greater than 55 μm. As described above, as the aerial image intensity increases and the alignment signal contrast decreases due to the second reflected light REL2, the first width PBW1 may be relatively large.

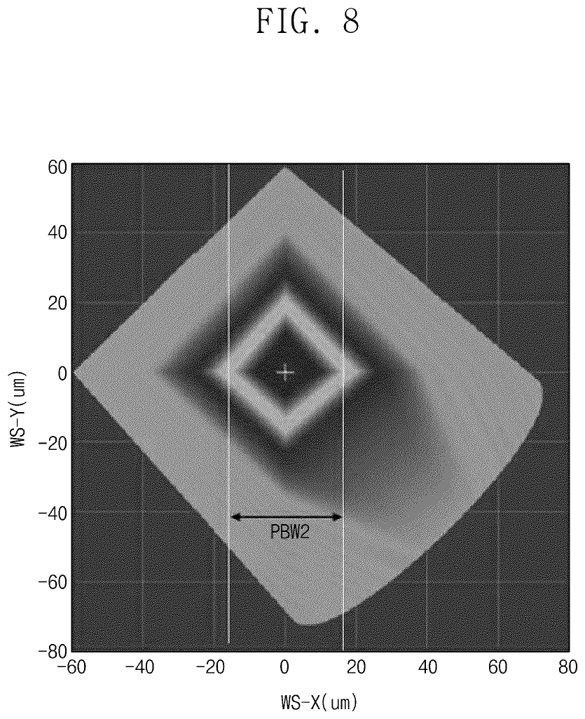

FIG. 7 is a schematic diagram for explaining an alignment process with a wafer using a reflective mask according to an embodiment of the inventive concept. FIG. 8 illustrates an aerial image intensity when an alignment sensor shown in FIG. 7 scans an alignment mark region.

Referring to FIG. 7, in a reflective mask MA according to the embodiment of the inventive concept, an anti-reflection pattern ARP may be provided in each of first and second alignment mark regions TMR1 and TMR2. The description of the anti-reflection pattern ARP may be substantially the same as that described above with reference to FIGS. 3 and 4. The absorption layer ABL in a region excluding an alignment mark TMP1 may include the anti-reflection pattern ARP formed of line-and-space type trenches.

Light for scanning of a first alignment sensor TIS1 may be reflected from the first alignment mark region TMR1. The light reflected from the first alignment mark region TMR1 may include a first reflected light REL1 and a second reflected light REL2. The first reflected light REL1 may be reflected from the first alignment mark TMP1. The second reflected light REL2 may be reflected from the absorption layer ABL and from the anti-reflection pattern ARP around the first alignment mark TMP1.

The second reflected light REL2 reflected from the absorption layer ABL and the second reflected light REL2 reflected from the anti-reflection pattern ARP may cause destructive interference with each other. Accordingly, unlike FIG. 5 described above, according to the present embodiment, the second reflected light REL2 may not reach the first alignment sensor TIS1 and only the first reflected light REL1 may be incident on the first alignment sensor TIS1 (and similarly with respect to the second alignment sensor TIS2).

The anti-reflection pattern ARP according to the present embodiment may reduce EUV reflectance of the absorption layer ABL of the EUV PSM. In other words, the anti-reflection pattern ARP may eliminate the second reflected light REL2 or reduce the intensity of the second reflected light REL2 For example, the anti-reflection pattern ARP formed on the absorption layer ABL of the alignment mark regions TMR1 and TMR2 may reduce the intensity of the second reflected light REL2 to 10% or less of the intensity of the first reflected light REL1.

The anti-reflection pattern ARP may be omitted in the absorption layer ABL of the outer auxiliary and central regions OSR and CER that transfers a pattern onto a substrate SUB (i.e., the wafer) through the EUV lithography process. The anti-reflection pattern ARP may reduce the reflectance of the absorption layer ABL, and thus the resolution of the EUV lithography process may be reduced when the anti-reflection pattern ARP is provided in the auxiliary and central regions OSR and CER.

The first and second alignment mark regions TMR1 and TMR2 for determining whether the reflective mask MA and the substrate SUB are aligned are not transferred onto the substrate SUB, but are only a scan target of the first and second alignment sensors TIS1 and TIS2. The anti-reflection pattern ARP may be selectively provided in the absorption layer ABL of the first and second alignment mark regions TMR1 and TMR2, and thus the alignment signal contrast may be increased to improve scan accuracy. The anti-reflection pattern ARP may be selectively provided only to the first and second alignment mark regions TMR1 and TMR2 (e.g., such that the auxiliary and/or central regions OSR and CER may be free of the anti-reflection pattern ARP), and thus the EUV lithography process may not be affected.

Referring to FIG. 8, a scan signal of the first alignment mark TMP1 of the reflective mask MA according to an embodiment of the inventive concept is illustrated. The scan signal of FIG. 8 may represent aerial image intensity. It may be seen that the image shown in FIG. 8 is clearer than the image shown in FIG. 6.

In the aerial image intensity of FIG. 8, a parabolic width may have a second width PBW2. The second width PBW2 may be smaller than the first width PBW1 of FIG. 6. For example, the second width PBW2 may be 30 μm to 45 μm. As described above, the anti-reflection pattern ARP according to the present embodiment may offset or otherwise reduce the intensity of the second reflected light REL2, and thus the aerial image intensity may decrease, the alignment signal contrast may increase, and the second width PBW2 may become relatively small.

The alignment process using the reflective mask MA according to the present embodiment may reduce the signal noise and increase the alignment signal contrast. As a result, the first alignment sensor TIS1 may accurately scan the first alignment mark region TMR1 and the second alignment sensor TIS2 may accurately scan the second alignment mark region TMR2, thereby determining whether the reflective mask MA and the substrate SUB are accurately aligned.

The anti-reflection pattern ARP may not be provided in the absorption layer ABL of the auxiliary and central regions OSR and CER requiring high reflectance, and thus the reflective mask MA according to the present embodiment may improve the resolution of the EUV lithography process. Meanwhile, the anti-reflection pattern ARP may selectively be provided only in the absorption layer ABL of the alignment mark regions TMR1 and TMR2 requiring low reflectance, and thus accurate scanning of the alignment marks through the alignment sensors TIS1, TIS2 may be achieved.

In another embodiment of the inventive concept, the anti-reflection pattern ARP may also be provided in the outer auxiliary region OSR and/or the inner auxiliary region ISR. The anti-reflection pattern ARP provided in the outer and inner auxiliary regions OSR and ISR may reduce reflectance of the absorption layer ABL of the outer and inner auxiliary regions OSR and ISR.

The anti-reflection pattern ARP may be omitted in the cell region (or cell) of the main region CRG. However, the anti-reflection pattern ARP may be provided in an inter-block region of the main region CRG. Cells in the main region CRG may correspond to functional blocks in the chip region of the substrate SUB. A cell of the main region CRG may correspond to a circuit cell or a memory cell of the functional block.

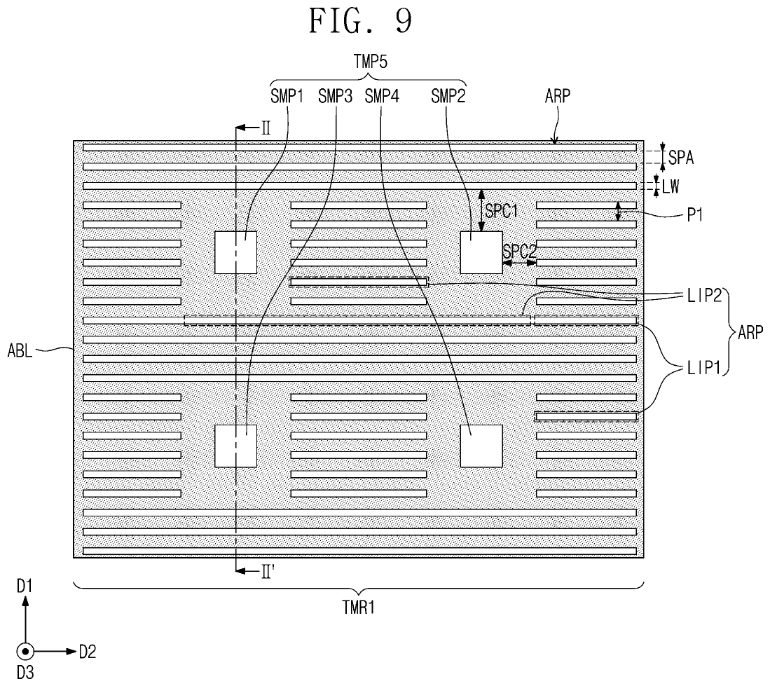

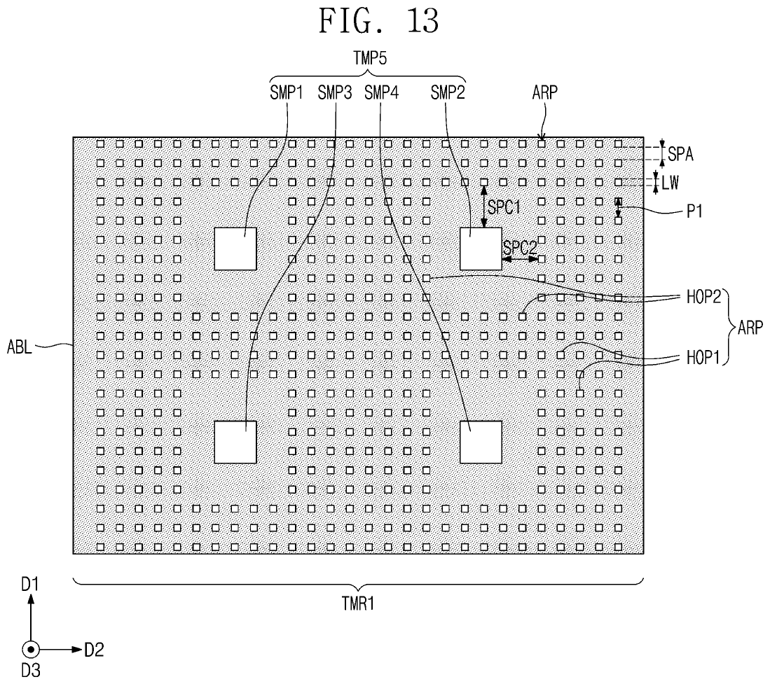

The anti-reflection pattern ARP provided in the inter-block region of the outer and inner auxiliary regions OSR and ISR and the main region CRG may have the same or different shape as/from the anti-reflection pattern ARP provided in the first and second alignment mark regions TMR1 and TMR2. For example, the anti-reflection pattern ARP provided in the inter-block region of the outer and inner auxiliary regions OSR and ISR and the main region CRG may have the shape of FIG. 13 to be described later, and the anti-reflection pattern ARP provided in the first and second alignment mark regions TMR1 and TMR2 may have the shape of FIG. 9 to be described later.

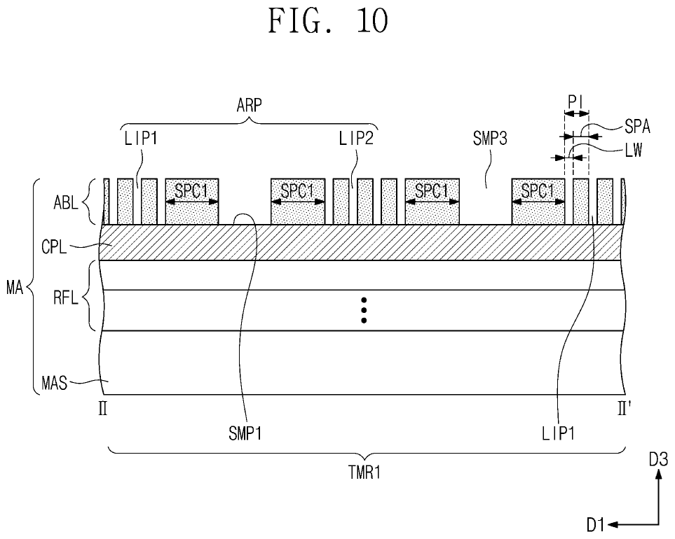

FIG. 9 is a plan view illustrating one of the alignment marks (e.g., a fifth alignment mark TMP5) of a first alignment mark region of a reflective mask of FIG. 3 according to an embodiment of the inventive concept, specifically. FIG. 10 is a cross-sectional view taken along line II-II′ of FIG. 9.

Referring to FIGS. 9 and 10, a reflective mask MA may include a mask substrate MAS, a reflective layer RFL, a capping layer CPL, and an absorption layer ABL. The capping layer CPL may be omitted. The absorption layer ABL may include at least one layer based on a ruthenium alloy or a tantalum alloy.

A fifth alignment mark TMP5 may include first to fourth mark patterns SMP1 to SMP4. The first to fourth mark patterns SMP1 to SMP4 may have a shape of two-dimensionally arranged contacts. Each of the first to fourth mark patterns SMP1 to SMP4 may have a tetragonal shape.

An anti-reflection pattern ARP surrounding the first to fourth mark patterns SMP1 to SMP4 may be provided. The anti-reflection pattern ARP may include first line patterns LIP1 disposed outside the first to fourth mark patterns SMP1 to SMP4, that is, the outside of the fifth alignment mark TMP5, and second line patterns LIP2 disposed in a region between the first to fourth mark patterns SMP1 the SMP4.

The first and second line patterns LIP1 and LIP2 may extend in a second direction D2 parallel to each other. The first and second line patterns LIP1 and LIP2 may have the same line width LW. The first and second line patterns LIP1 and LIP2 may have the same interval SPA. The first and second line patterns LIP1 and LIP2 may be arranged in a first direction D1 with a constant pitch PI. That is, the anti-reflection pattern ARP according to the present embodiment may include regular line-and-space patterns.

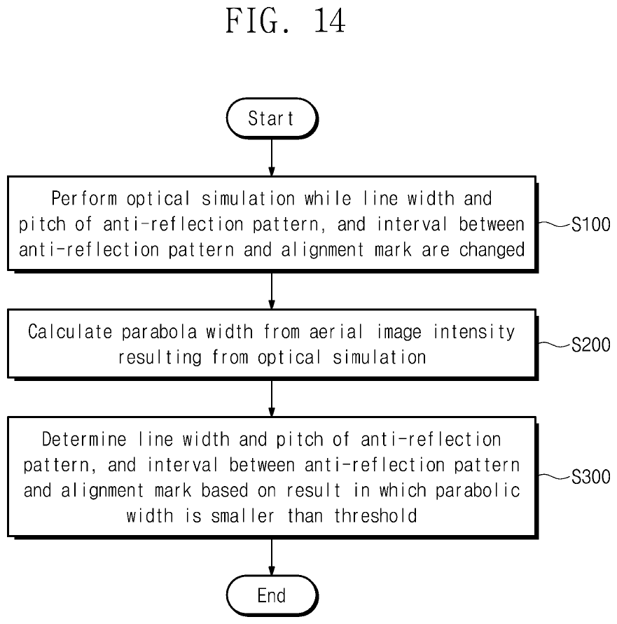

In an embodiment of the inventive concept, the line width LW may be smaller than the interval SPA. The sum of the line width LW and the interval SPA may be defined as the pitch PI. For example, the pitch PI may be 25 nm to 50 nm. The line width LW may be 10 nm to 25 nm. The line width LW and the pitch PI of the anti-reflection pattern ARP may be variable depending on a type of illumination system used in the EUV lithography process. An appropriate line width LW and pitch PI may be selected depending on a method of designing the anti-reflection pattern ARP to be described later (refer to FIG. 14 to be described later).

The anti-reflection pattern ARP may be spaced apart from the mark patterns SMP1 to SMP4 by a predetermined interval. The interval in the first direction D1 between the anti-reflection pattern ARP and the mark patterns SMP1 to SMP4 may be a first interval SPC1. The interval in the second direction D2 between the anti-reflection pattern ARP and the mark patterns SMP1 to SMP4 may be a second interval SPC2. The first interval SPC1 and the second interval SPC2 may be substantially the same as or different from each other. In an embodiment, the first and second intervals SPC1 and SPC2 may be greater than the pitch PI of the anti-reflection pattern ARP. Appropriate values for the first and second intervals SPC1 and SPC2 may also be selected depending on the method of designing the anti-reflection pattern ARP to be described later (refer to FIG. 14 to be described later).

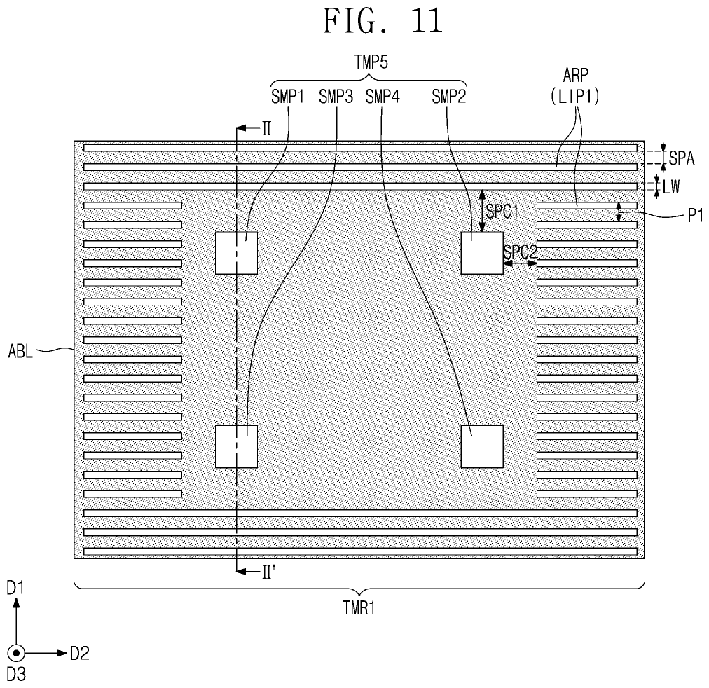

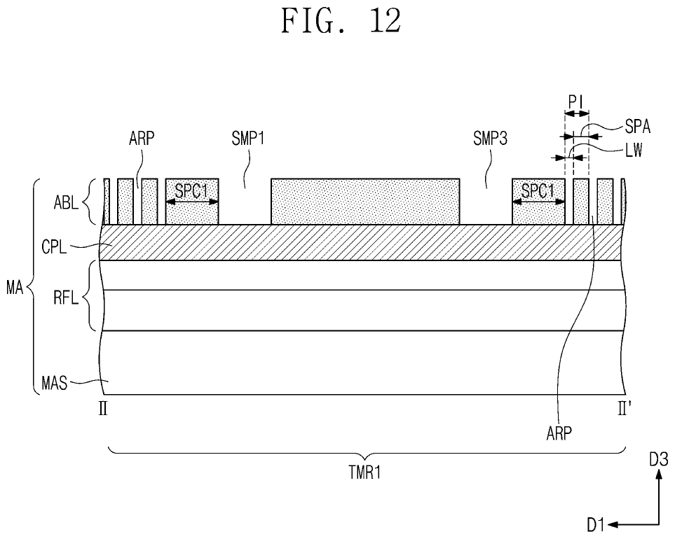

FIG. 11 is a plan view illustrating one of the alignment marks (e.g., a fifth alignment mark TMP5) in a first alignment mark region of a reflective mask of FIG. 3 according to another embodiment of the inventive concept. FIG. 12 is a cross-sectional view taken along line II-II′ of FIG. 11. FIG. 13 is a plan view illustrating one of the alignment marks (e.g., a fifth alignment mark TMP5) of a first alignment mark region of a reflective mask of FIG. 3 according to another embodiment of the inventive concept, specifically. In the embodiments to be described later, detailed descriptions of technical features overlapping those described above with reference to FIGS. 9 and 10 will be omitted, and differences will be described in detail.

Referring to FIGS. 11 and 12, an anti-reflection pattern ARP may include first line patterns LIP1 disposed outside the first to fourth mark patterns SMP1 to SMP4, that is, outside of the fifth alignment mark TMP5. Second line patterns LIP2 disposed in a region between the first to fourth mark patterns SMP1 to SMP4 may be omitted. A region between the first to fourth mark patterns SMP1 to SMP4 may be filled only or primarily with the absorption layer ABL. The first line patterns LIP1 may be arranged in a first direction D1 with a constant pitch PI. The first line patterns LIP1 may have the same line width LW.

Referring to FIG. 13, an anti-reflection pattern ARP may have the shape of two-dimensionally arranged contacts (or holes). The anti-reflection pattern ARP may include first hole patterns HOPI disposed outside of the first to fourth mark patterns SMP1 to SMP4, that is, outside the fifth alignment mark TMPS, and second hole patterns HOP2 disposed in a region between the first to fourth mark patterns SMP1 to SMP4.

The first and second hole patterns HOP1 and HOP2 may have the same width LW. The first and second hole patterns HOP1 and HOP2 may have the same interval SPA. The first and second hole patterns HOP1 and HOP2 may be arranged in a first direction D1 and a second direction D2 with a constant or uniform pitch PI.

The anti-reflection pattern ARP according to the inventive concept may be used without limitation as long as the anti-reflection pattern ARP is in a form of a uniformly repeated pattern. The anti-reflection pattern ARP may be configured in a form capable of reducing the reflectance of the absorption layer ABL through destructive interference.

FIG. 14 is a flowchart illustrating a method of designing an anti-reflection pattern according to embodiments of the inventive concept. The method may be implemented by computer readable program instructions stored in a non-transitory storage medium, which may be executed by a processor to perform the operations of the flowchart of FIG. 14. Referring to FIG. 14, a line width LW and a pitch PI of an anti-reflection pattern ARP described above with reference to FIGS. 9 and 10 may be determined to be values capable of reducing or minimizing reflectance of an absorption layer ABL.

Even with the same anti-reflection pattern ARP, reflectance of an absorption layer ABL may be variable depending on a type of illumination system (e.g., on-axis illumination or off-axis illumination) used in an EUV lithography process. Therefore, the line width LW and pitch PI of the anti-reflection pattern ARP should be determined depending on the EUV lithography process to be applied and the illumination system to be used.

To increase alignment signal contrast of the alignment mark regions TMR1 and TMR2, the intervals SPC1 and SPC2 between the alignment mark TMP and the anti-reflection pattern ARP may be important as well as the line width LW and pitch PI of the anti-reflection pattern ARP that determines the reflectance of the absorption layer ABL.

In summary, while three variables of the line width LW and pitch PI of the anti-reflection pattern ARP and the intervals SPC1 and SPC2 between the anti-reflection pattern ARP and the alignment mark TMP are changed, an optical simulation may be performed for the alignment mark regions TMR1 and TMR2 in block S100.

As a result of performing the optical simulation, the aerial image intensity described above with reference to FIGS. 6 and 8 for the alignment mark regions TMR1 and TMR2 may be obtained. The parabola or parabolic width in the aerial image intensity (e.g., PBW1 in FIG. 6 and PBW2 in FIG. 8) may be measured. The parabolic width of each of a plurality of cases in which the three variables are changed may be calculated in block S200.

Results smaller than a threshold among the calculated parabolic widths may be extracted. The threshold may be a minimum value of the parabolic width that the alignment sensors TIS1 and TIS2 are capable of reading without error. For example, in the case of the first alignment mark TMP1, the minimum value of the parabolic width readable by the alignment sensors TIS1 and TIS2 installed in the EUV equipment may be 45 μm. In this case, results of 45 μm or less among the calculated parabolic widths may be extracted as appropriate data.

The anti-reflection pattern ARP may be designed based on the values of three variables, that is, the line width LW, the pitch PI, and the intervals SPC1 and SPC2, of the extracted results in block S300. For example, when the line width of the anti-reflection pattern is 12 nm, the pitch is 32 nm, the interval is 50 nm and the parabola width of the optical simulation appears to be the minimum, the line width LW, the pitch PI, and the intervals SPC1 and SPC2 of the anti-reflection pattern ARP of FIG. 9 may be determined, respectively, based on these values.

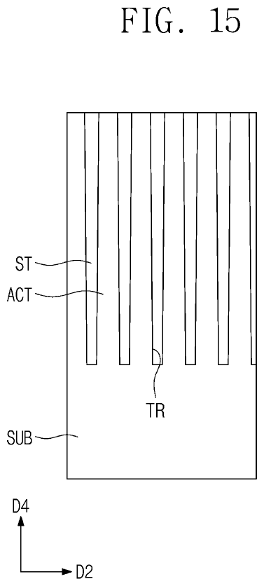

FIGS. 15 to 18 are diagrams for illustrating a method of manufacturing a semiconductor device according to embodiments of the inventive concept. In detail, FIGS. 15 to 18 are cross-sectional views of a wafer. A manufacturing process of DRAM among semiconductor devices will be exemplarily described.

Referring to FIG. 15, active patterns ACT may be formed in a chip region of a substrate SUB by patterning an upper portion of the substrate SUB. A trench TR may be defined between the active patterns ACT. A device isolation layer ST filling the trench TR may be formed.

According to an embodiment of the inventive concept, a patterning process for forming the active patterns ACT may include a lithography process using EUV. The lithography process using EUV may include exposure and development processes using EUV irradiated onto a photoresist layer.

In the exposure process using EUV, the reflective mask MA according to embodiments of the inventive concept may be used. The first and second alignment sensors TIS1 and TIS2 of FIG. 1 may scan the first and second alignment mark regions TMR1 and TMR2, respectively, to accurately align the reflective mask MA and the substrate SUB. Thereafter, an exposure process using EUV may be performed. The above-described anti-reflection pattern ARP may be provided in the first and second alignment mark regions TMR1 and TMR2 (refer to FIGS. 9 and 10). Designing the anti-reflection pattern ARP to be applied to the reflective mask MA of the exposure process is the same as described above with reference to FIG. 14.

The photoresist layer may be an organic photoresist containing an organic polymer such as polyhydroxystyrene. The organic photoresist may further include a photosensitive compound that responds to EUV. The organic photoresist may further include a material having a high EUV absorption rate, for example, an organometallic material, an iodine-containing material, or a fluorine-containing material. As another example, the photoresist layer may be an inorganic photoresist containing an inorganic material such as tin oxide.

The photoresist layer may be formed to have a relatively thin thickness. Photoresist patterns may be formed by developing the photoresist layer exposed to EUV. In a plan view, the photoresist patterns may have a line or linear shape extending in one direction, an island shape, a zigzag shape, a honeycomb shape, or a circular shape, but are not limited thereto.

One or more mask layers stacked under the photoresist patterns may be patterned using the photoresist patterns as an etch mask to form mask patterns. A target layer may be patterned using the mask patterns as an etch mask to form desired patterns on the wafer.

As a comparative example of the inventive concept, a multi-patterning technique (MPT) using two or more photomasks is required to form patterns having a fine pitch on the wafer. On the other hand, in the case of performing the EUV lithography process according to the embodiment of the inventive concept, the active patterns ACT having a fine pitch may be formed even with a single photomask.

For example, a minimum pitch between the active patterns ACT implemented by the EUV lithography process of the present embodiment may be 45 nm or less. That is, by performing the EUV lithography process, accurate and fine active patterns ACT may be implemented without a multi-patterning technique. The reflective mask MA according to the embodiments of the inventive concept described above may be used as a photomask for forming the active patterns ACT.

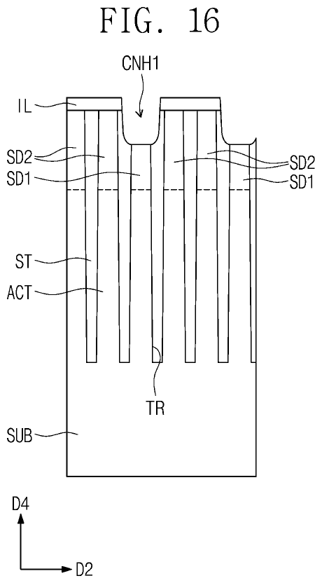

Referring to FIG. 16, a plurality of buried gate electrodes (not shown) crossing the active patterns ACT may be formed on the substrate SUB. First and second source/drain regions SD1 and SD2 may be formed on the active patterns ACT by performing an ion implantation process on the active patterns ACT. An insulating layer IL may be formed on the entire surface of the substrate SUB. For example, the insulating layer IL may have a multi-layer structure in which a silicon oxide layer and a silicon oxynitride layer are stacked.

The insulating layer IL may be patterned to form first contact holes CNH1 exposing the first source/drain regions SD1 of the active patterns ACT, respectively. When the first contact hole CNH1 is formed, an upper portion of the first source/drain region SD1 may be recessed. When the first contact hole CNH1 is formed, an upper portion of the device isolation layer ST around the first source/drain region SD1 may be recessed. In an embodiment of the inventive concept, the first contact holes CNH1 may be formed using the EUV lithography process described above.

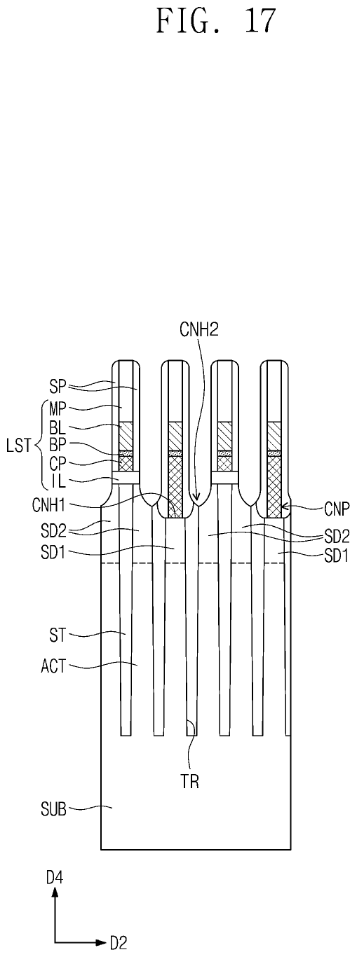

Referring to FIG. 17, line structures LST extending parallel to each other may be formed on the active patterns ACT. Each of the line structures LST may include a conductive pattern CP, a barrier pattern BP, a bit line BL, and a mask pattern MP that are sequentially stacked. The conductive pattern CP may include a contact portion CNP that fills the first contact hole CNH1 and is connected to the first source/drain region SD1. The contact portion CNP may be in direct contact with the first source/drain region SD1. In an embodiment of the inventive concept, the mask patterns MP may be formed using the EUV lithography process described above.

The barrier pattern BP may suppress diffusion of a metal material in the bit line BL into the conductive pattern CP. The bit line BL may be electrically connected to the first source/drain region SD1 through the barrier pattern BP and the conductive pattern CP. The conductive pattern CP may include a doped semiconductor material (doped silicon, doped germanium, etc.). The barrier pattern BP may include a conductive metal nitride (e.g., titanium nitride or tantalum nitride). The bit line BL may include a metal material (e.g., titanium, tantalum, tungsten, copper, or aluminum).

A pair of spacers SP may be formed on both (e.g., opposing) sidewalls of each of the line structures LST. The spacers SP may include a silicon oxide layer, a silicon nitride layer, and/or a silicon oxynitride layer.

The entire surface of the substrate SUB may be etched using the spacers SP and the mask patterns MP as a mask to form second contact holes CNH2 exposing the second source/drain regions SD2, respectively. When the second contact hole CNH2 is formed, an upper portion of the second source/drain region SD2 may be recessed.

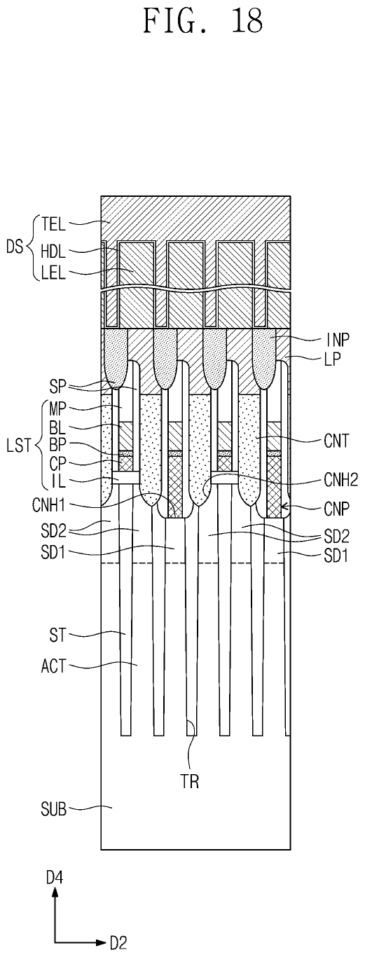

Referring to FIG. 18, the second contact holes CNH2 may be filled with a conductive material, and thus contacts CNT may be formed in the second contact holes CNH2, respectively. The contacts CNT may be connected to the second source/drain regions SD2. The conductive material filling the second contact holes CNH2 may include a doped semiconductor material.

Landing pads LP may be respectively formed on the contacts CNT on a chip region. In detail, a metal layer may be formed on the contacts CNT and the line structures LST. A plurality of landing pads LP may be formed by patterning the metal layer. An insulating pattern INP may be formed by filling a space between the plurality of landing pads LP with an insulating material. In an embodiment of the inventive concept, patterning the landing pads LP may include the above-described EUV lithography process.

Subsequently, first electrodes LEL may be respectively formed on the landing pads LP. A dielectric layer HDL may be conformally formed on the first electrodes LEL. A second electrode TEL may be formed on the dielectric layer HDL. The first electrode LEL, the dielectric layer HDL, and the second electrode TEL may constitute a data storage element DS, for example, a capacitor. Although not shown, wiring layers (e.g., M1, M2, M3, M4 . . . ) stacked on the second electrode TEL may be formed.

The alignment process using the reflective mask according to the inventive concept may reduce the signal noise and increase the alignment signal contrast. Accordingly, the alignment sensor of the wafer stage may accurately scan the alignment mark region of the reflective mask to determine whether the reflective mask and the wafer are correctly aligned.

The reflective mask according to the inventive concept may omit the anti-reflection pattern in the absorption layer of the main region requiring higher reflectance to improve the resolution of the EUV lithography process. Meanwhile, the anti-reflection pattern may be selectively provided (e.g., in portions of the absorption layer) in the alignment mark region requiring lower reflectance, to achieve the accurate scanning of the alignment mark without affecting the EUV lithography process.

While embodiments are described above, a person skilled in the art may understand that many modifications and variations are made without departing from the scope of the inventive concept defined in the following claims. Accordingly, the example embodiments of the inventive concept should be considered in all respects as illustrative and not restrictive, with the scope of the inventive concept being indicated by the appended claims.

What is claimed is:

1. A reflective mask comprising:
a mask substrate, a reflective layer on the mask substrate, and an absorption layer on the reflective layer,
wherein the reflective mask comprises a main region, an out-of-band region surrounding the main region, and an alignment mark region outside a periphery of the out-of-band region,
wherein the absorption layer in the alignment mark region comprises an alignment mark and an anti-reflection pattern adjacent the alignment mark, and
wherein the anti-reflection pattern comprises line-and-space patterns having a predetermined line width and a predetermined pitch in the alignment mark region.

2. The reflective mask of claim 1, wherein the absorption layer comprises a ruthenium alloy or a tantalum alloy,
wherein the reflective mask is an extreme ultraviolet (EUV) phase inversion mask, and
wherein the alignment mark is configured to provide a first reflectance in the alignment mark region, and the anti-reflection pattern is configured to provide a second reflectance that is less than the first reflectance in the alignment mark region.

3. The reflective mask of claim 1, wherein the anti-reflection pattern is selectively provided in the alignment mark region such that cells of the main region are free of the anti-reflection pattern, and wherein the predetermined line width is smaller than a width of the alignment mark in a first direction.

4. The reflective mask of claim 1, wherein the alignment mark comprises a plurality of mark patterns,
wherein the line-and-space patterns comprise:
first line patterns outside a periphery of the alignment mark; and
second line patterns inside the periphery of the alignment mark in a region between the plurality of mark patterns.

5. The reflective mask of claim 1, wherein the alignment mark comprises a plurality of mark patterns,
wherein the line-and-space patterns are not provided in a region between the plurality of mark patterns.

6. An extreme ultraviolet (EUV) phase shift mask comprising:
a mask substrate, a reflective layer on the mask substrate, and an absorption layer on the reflective layer,
wherein the EUV phase shift mask comprises a main region, an out-of-band region surrounding the main region, and an alignment mark region outside a periphery of the out-of-band region,
wherein the absorption layer in the alignment mark region comprises an alignment mark and an anti-reflection pattern adjacent the alignment mark, and
wherein the alignment mark is configured to provide a first reflectance in the alignment mark region, and the anti-reflection pattern is configured to provide a second reflectance that is less than the first reflectance in the alignment mark region.

7. The EUV phase shift mask of claim 6, wherein the anti-reflection pattern comprises a plurality of line patterns,
wherein the plurality of line patterns have a same predetermined line width that is smaller than a width of the alignment mark in a first direction, and
wherein the plurality of line patterns are arranged at a predetermined pitch in the first direction.

8. The EUV phase shift mask of claim 7, wherein the alignment mark comprises a plurality of mark patterns,
wherein the plurality of line patterns comprise:
first line patterns outside a periphery of the alignment mark; and
second line patterns disposed inside the periphery of the alignment mark in a region between the plurality of mark patterns.

9. The EUV phase shift mask of claim 7, wherein the alignment mark comprises a plurality of mark patterns,
wherein the plurality of line patterns are not provided in a region between the plurality of mark patterns.

10. The EUV phase shift mask of claim 7, wherein the plurality of line patterns are spaced apart from the alignment mark by a predetermined interval.

11. The EUV phase shift mask of claim 6, wherein the anti-reflection pattern comprises a plurality of hole patterns,
wherein the plurality of hole patterns are two-dimensionally arranged in first and second directions,
wherein the plurality of hole patterns have a same predetermined width, and
wherein the plurality of hole patterns are arranged at a predetermined pitch in the first direction and/or in the a second direction.

12. The EUV phase shift mask of claim 6, wherein the alignment mark and the anti-reflection pattern expose portions of the reflective layer, and
wherein a remaining region of the alignment mark region, which is free of the alignment mark and the anti-reflection pattern, comprises the absorption layer on the reflective layer.

13. The EUV phase shift mask of claim 6, wherein the absorption layer comprises a ruthenium alloy or a tantalum alloy.

14. The EUV phase shift mask of claim 6, wherein the anti-reflection pattern is selectively provided in the alignment mark region such that cells of the main region are free of the anti-reflection pattern.

15. The EUV phase shift mask of claim 6, wherein the alignment mark region is configured to indicate an alignment between the EUV phase shift mask and a wafer to an alignment sensor of a wafer stage.

16. A method of fabricating an anti-reflection pattern of a reflective mask comprising a mask substrate, a reflective layer on the mask substrate, and an absorption layer on the reflective layer, wherein the reflective mask comprises a main region, an out-of-band region surrounding the main region, and an alignment mark region outside a periphery of the out-of-band region, and the absorption layer in the alignment mark region comprises an alignment mark and an anti-reflection pattern adjacent the alignment mark, the method comprising:
executing, by a processor, computer readable program instructions stored in a non-transitory storage medium to perform operations comprising:
performing optical simulation during which a line width and a pitch of line-and-space patterns in the absorption layer in the alignment mark region, and an interval between the line-and-space patterns and the alignment mark, are changed;
calculating a parabolic width from an aerial image intensity resulting from the optical simulation; and
determining the line width, the pitch, and the interval based on a result of the calculating in which the parabolic width is smaller than a threshold.

17. The method of claim 16, wherein the threshold is a minimum value of a parabolic width that an alignment sensor of a wafer stage is configured to read without error.

18. The method of claim 16, wherein the parabolic width decreases as the anti-reflection pattern reduces a reflectance of the absorption layer in the alignment mark region.

19. The method of claim 16, wherein the absorption layer comprises a ruthenium alloy or a tantalum alloy, and wherein the reflective mask is an extreme ultraviolet (EUV) phase shift mask.

20. The method of claim 16, further comprising:
fabricating the anti-reflection pattern comprising the line-and-space patterns based on the line width, the pitch, and the interval.
